(19) United States
(12) Patent Application Publication
(10) Pub. No.: US 2015/0008431 A1
(43) Pub. Date: Jan. 8, 2015

(54) METHOD AND LAYOUT FOR DETECTING DIE CRACKS

(71) Applicant: NANYA TECHNOLOGY CORPORATION, Tao-Yuan Hsien (TW)

(72) Inventor: Anthony David VECHES, Boise, ID (US)

(21) Appl. No.: 13/935,496

(22) Filed: Jul. 4, 2013

(51) Int. Cl. H01L 21/66; G01R 31/02; G01R 31/26

(52) U.S. Cl. CPC H01L 22/32; H01L 22/12; G01R 31/2601; G01R 31/025
USPC 257/48; 438/666; 324/762.03

(57) ABSTRACT

A method of detecting a crack in a semiconductor die is provided. The method includes the following steps. A semiconductor die having an outer edge is provided, wherein a conductive feature is formed on semiconductor die along the outer edge. The conductive feature is biased, and a leakage current of the semiconductor die is measured, such that the crack propagating in the semiconductor the is detected. A semiconductor the with a layout for detecting a die crack and the method of manufacturing it are also provided. The semiconductor the includes a semiconductor the having an cuter edge, and a conductive feature on the semiconductor die along the outer edge. The conductive feature is configured to be biased by an external pin.

### BACKGROUND

1. Technical Field

The present disclosure relates to a semiconductor die, and more particularly, to a semiconductor die with a layout for detecting a die crack, and a method of detecting the die crack.

2. Description of Related Art

In semiconductor processes, electronic circuits are rr anufactured as integrated circuits (“ICs” in semiconductor chips, which are routinely fabricated in large groups as part of a single semiconductor wafer.

At the conclusion of the processing steps to form the individual dice, a so-called dicing operation is performed on the wafer to cut out the individual dice. Afterwards, the dice may be packaged or directly mounted to a printed circuit board. Conventional semiconductor dice are routinely cut out from the wafer as rectangular shapes. The dicing operation is a mechanical cutting action which is performed with a dicing saw. In this regard, significant stresses are inevitably imposed on the individual dice in cutting, no matter how carefully the operation is conducted. These stresses and impact loads during the cutting can cause microscopic fractures in the dice, particularly at the die edges and corners. Once the cut dice are mounted to a package substrate or printed circuit board of one sort or another, the cracks introduced during cutting may propagate further into the center of the dice due to thermal stresses and other mechanical stresses induced. Modern semiconductor chips include an interconnect stack consisting of plural metallization and interlevel dielectric layers. During or subsequent to the dicing operation, delaminations of the interlevel dielectric layers can occur and propagate toward the sensitive interior active area of the die. A delamination can possibly proceed laterally inward. in addition, new cracks may form, particularly near the corners which create so-called stress risers by virtue of their geometries.

Currently, the die cracks can only be detected through functional array to fails, or catastrophic shorting between supply buses. Therefore, there is a need for a die in which the cracks can be instantly detected upon generation.

### SUMMARY The present disclosure provides a method of detecting a crack in a semiconductor die, a semiconductor die with a layout for detecting a die crack and a method for manufacturing thereof.

One embodiment of the present disclosure is to provide a method of detecting a crack in a semiconductor die. The method includes the following steps. A semiconductor die having an outer edge is provided, wherein a conductive feature is formed on semiconductor die along the outer edge. The conductive feature is biased, and a leakage current of the semiconductor die is measured, such that the crack propagating in the semiconductor die is detected.

Another embodiment of the present disclosure is to provide a semiconductor die with a layout for detecting a die crack. The semiconductor die includes a semiconductor die having an outer edge, and a conductive feature on the semiconductor die along the outer edge. The conductive feature is configured to be biased by an external pin.

Another embodiment of the present disclosure is to provide a method of manufacturing a semiconductor die with a layout for detecting a die crack. The method includes the following steps. The semiconductor die is fabricated having an outer edge: and a conductive feature is formed on the semiconductor die along the outer edge. In which, the conductive feature is configured to be biased by an external pin.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a schematic plan view of a semiconductor wafer including a plurality of die according to an embodiment of the present disclosure;

FIG. 2 is a close up view of a die of FIG. 1 that includes a layout for detecting a die crack according to one embodiment of the present disclosure;

FIG. 3 shows a plan view of the single die of FIG. 2 after the singulation of die according to one embodiment of the present disclosure;

FIG. 4 is a flow chart of a method of detecting a crack in a semiconductor die according to an embodiment of the present disclosure.

FIG. 5 is a flow chart of a method of manufacturing a semiconductor die with a layout for detecting a die crack; and

### DETAILED DESCRIPTION

The making and using of the embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

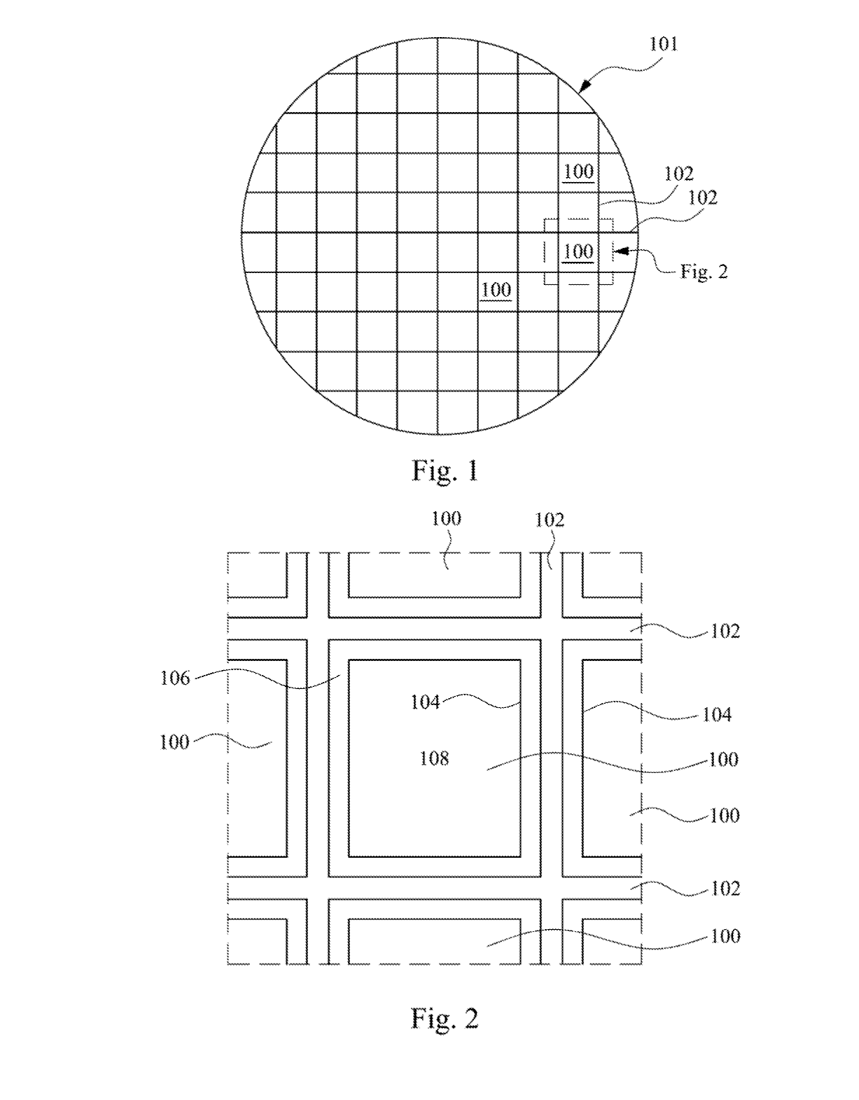

FIG. 1 shows a schematic plan view of a semiconductor wafer 101 including a plurality of die 100 according to an embodiment of the present to disclosure. The wafer 101 may include alignment features such as notches or straight edges (not shown). The wafer 101 includes the dies 100, which may be square or rectangular in shape, formed across a top surface of the wafer 101. Each die 100 includes a central region 108 that has an active region with functioning circuitry for the IC or a semiconductor device.

FIG. 2 is a close up view of a die 100 of FIG. 1. Each die 100 includes a layout of a metal bus 104 is placed around the perimeter region 106 (i.e. the outer edge) of the die 101, to be used for detecting a die crack according to one embodiment of the present disclosure. The metal bus 104 is configured to connect to an external pin (not shown), which the electrical connection allows a voltage to be applied on the metal bus 104 and measure a leakage current of the die 100 in case any crack occurs therein after the dicing operation. In an embodiment, the semiconductor die 100 comprise two adjacent conductive paths around the perimeter, wherein an outer conductive path is an off-die barrier structure, and an inner conductive path is an elevated voltage bus for electrical fuse operations. As an example, the metal bus 104 can be a perimeter routing of an elevated voltage used for electrical fuse operations in the IC. The existing hardware supports applying external voltages on the pin. Since this bus already encounters elevated voltage, the layout of the metal bus 104 is able to accelerate the identification of a crack, the layout equips the ability to measure low level of the leakage current according to the embodiments of the present disclosure.

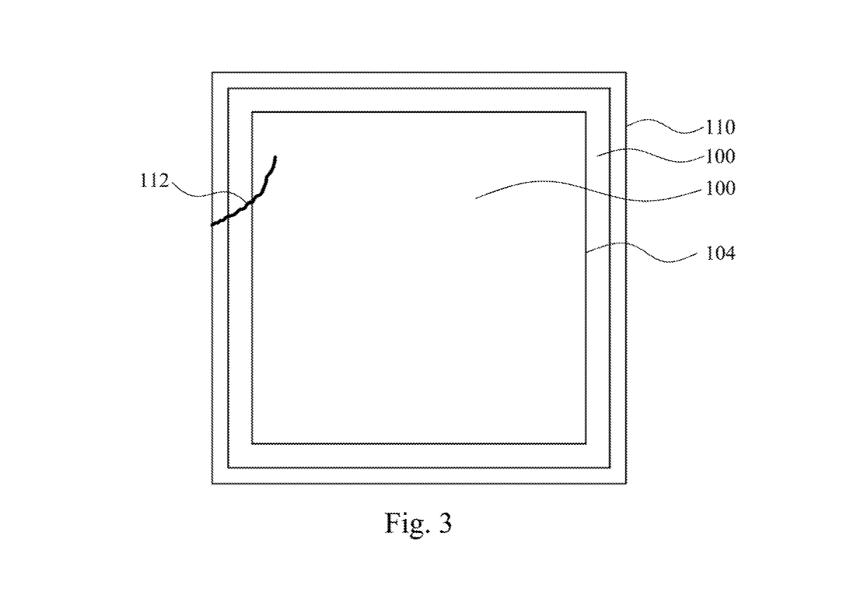

FIG. 3 shows a plan view of the single die of FIG, 2 after the singulation of die according to one embodiment of the present disclosure. At the end of the manufacturing process, a saw is used to singulate the dies 100 detaching the to die 100 from adjacent die 100. Referring to FIG. 2, the dies 100 are separated from each other by scribe line regions 102 disposed between the dies 100. The scribe line regions 102 are located at the perimeter of the die 100, and the saw cuts the wafer 101 at the scribe line regions 102. As example, the singulation of the die 100 may also be performed by laser dicing or laser scribing.

As an embodiment of the present disclosure, in FIG. 3 the die 100 includes an off-die barrier structure 110 formed around the edge of the perimeter region 106 of the die 100. Upon the sigulation of the dies 100, a die crack 112 is induced from the off-die barrier structure 110 across the metal bus 104, In the case of the die crack, metal migration creates a resistive short between the barrier structure 110 and the metal bus 104. The application of an elevated voltage on the metal bus 104 through an external pin (not shown) allows a leakage current between the metal bus 104 and an off-die barrier structure 110 to be measured, so as to identify the die crack. This will aid in the detection of die crack originating from the saw Imes.

It is noteworthy that the metal bus 104, as the embodiment of the present disclosure, can be any kinds of layouts of conductive feature along the perimeter region 106 of the die 100, as long as being connecting the circuitry in the die 100 to the external power source (not shown).

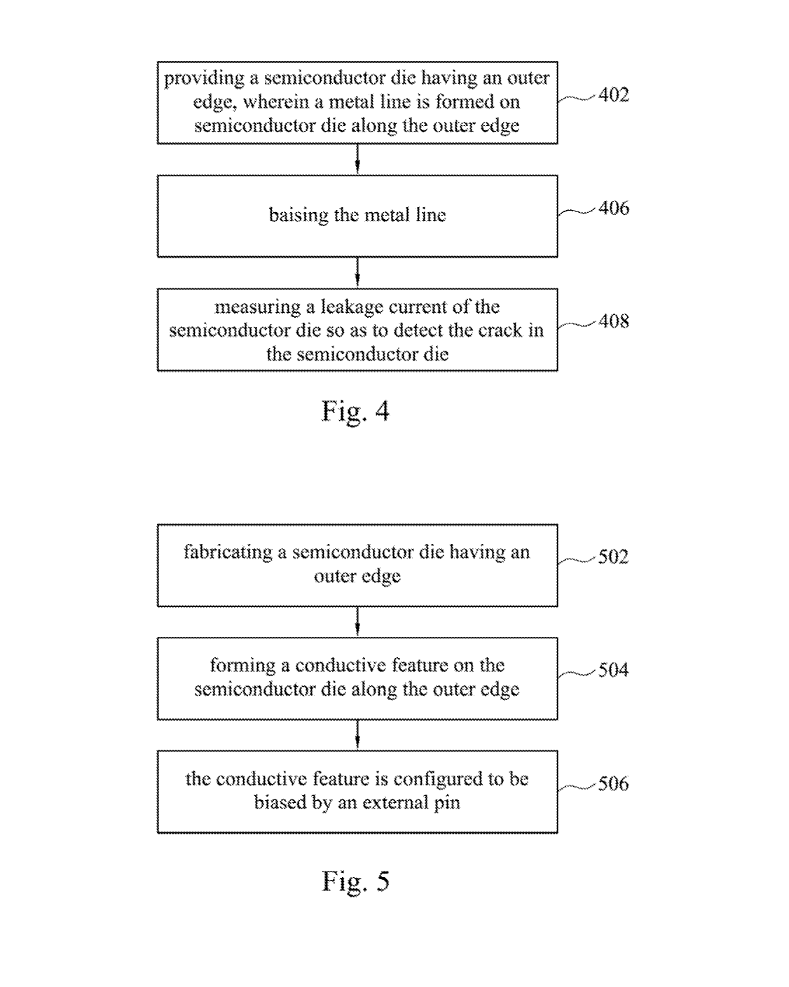

FIG. 4 is a flow chart of a method of detecting a crack in a semiconductor die as shown in FIG. 3, In an embodiment of the present disclosure, the method includes the following steps. At step 402, a sem conductor die having an outer edge is provided, wherein a conductive feature is formed on semiconductor die along the outer edge. At step 406, the conductive feature is io biased, and next a leakage current of the semiconductor die is measured at step 408, such that the crack, even at its very initial stage, already existing in or propagating in the semiconductor die is detected.

As an embodiment, the semiconductor die 100 comprises an off-die barrier structure 110 around the perimeter of the outer edge thereof. In an embodiment, the semiconductor die 100 comprise two adjacent conductive paths around the perimeter, wherein an outer conductive path (i.e,, conductive feature) is an off-die barrier structure, and an inner conductive path is an elevated voltage bus for electrical fuse operations. In an embodiment, the conductive feature is a metal line, and the metal line is extend from a bus of the semiconductor die 100. For example, the bus is an elevated voltage used for electrical fuse operations in the semiconductor die 100.

The conductive feature I ke the metal bus 104 can be formed by performing a dry etching process or a wet etching process.

In FIG. 5, it is shown a flow chart of a method of manufacturing a semiconductor die with a layout for detecting a die crack according to an embodiment of the present disclosure. In the embodiment, the method includes the following steps. At stage 502, the semiconductor die 100 is fabricated having an outer edge. At stage 504, a conductive feature is formed on the semiconductor die along the outer edge. Next, at stage 506, the conductive feature is configured to be biased by an external pin.

As an embodiment, the semiconductor die 100 comprises an off-die barrier structure 110 around the perimeter of the outer edge thereof, In an embodiment, the conductive feature is a metal line, and the metal line is extend from a bus of the semiconductor die 100. For example, the bus is an elevated voltage used for electrical fuse operations bus of transmitting internal signal in the semiconductor die 100.

Given the above, the die features a metal bus placed around the perimeter of the die that will connect to an external pin and allow the application of a voltage on the bus, so as to measure a leakage current between the bus and an off-die barrier structure. This will aid in the detection of die crack originating from the saw lines. Further, the bus can be the grounded bus with an additional routing around the perimeter of the die. The grounded bus already encounters elevated voltage which gives the ability to measure low level of the leakage current and thus accelerates the identification of a crack. Moreover, the existing hardware supports the application of external voltages on the pin.

Although embodiments of the present disclosure and their advantages have been described in detail, they are not used to limit the present disclosure. It should be understood that various changes, substitutions and alterations can be made herein without departing from the spirit and scope of the present disclosure. Therefore, the protecting scope of the present disclosure should be defined as the following claims.

1. A method of detecting a crack in a semiconductor die, comprising:
providing a semiconductor the having an outer edge. wherein a conductive feature is formed on semiconductor die along the outer edge;
biasing the conductive feature; and
measuring a leakage current of the semiconductor die so as o detect the crack in the semiconductor die,

2. The method of claim 1, wherein the conductive feature is a metal line.

3. The method of claim 2, wherein the metal line is electrically connected to an external pin configured to apply an elevated voltage to the metal line.

4. The method of claim 3, wherein the semiconductor die comprises a off-die barrier structure around the perimeter of the outer edge.

5. The method of claim 4, wherein the semiconductor die comprise two adjacent conductive paths around the perimeter, wherein an outer conductive path is an off-die barrier structure, and an inner conductive path is an elevated voltage bus for electrical fuse operations.

6. The method of claim 4, wherein the step of measuring the leakage current is to measure the leakage current between the metal line the off-die barrier structure.

7. The method of claim 3, wherein the metal line is extended from a bus of the semiconductor die.

8. The method of claim 7, wherein the bus is a grounded bus.

9. A method of manufacturing a semiconductor die with a layout for detecting a die crack, comprising the steps of:
fabricating a semiconductor die having an outer edge; and
forming a conductive feature on the semiconductor die along the outer edge, wherein the conductive feature is configured to be biased by an external pin.

10. The method of claim 9, wherein the semiconductor die comprises a off-die barrier structure around the perimeter of the outer edge.

11. The method of claim 4, wherein the off-die barrier structure is a GWOT.

12. The method of claim 9, wherein the conductive feature is a metal line.

13. The method of claim 12, wherein the metal line is extend from a bus of the semiconductor die.

14. The method of claim 13, wherein the bus is a grounded bus.

15. A semiconductor die with a layout for detecting a die crack, comprising:
a semiconductor die having an outer edge; and
a conductive feature on the se iconductor die along the outer edge, wherein the conductive feature is configured to be biased by an external pin.

16. The semiconductor die of claim 15, wherein the semiconductor die comprises a off-die barrier structure around the perimeter of the outer edge.

17. The method of claim 16, wherein the semiconductor die comprise two adjacent conductive paths around the perimeter, wherein an outer conductive path is an off-die barrier structure, and an inner conductive path is an elevated voltage bus for electrical fuse operations.

18. The semiconductor die of claim 15, wherein the conductive feature is a metal line.

19. The semiconductor die of claim 18 wherein the metal line is extend from a bus of the semiconductor die.

20. The semiconductor die of claim 19, wherein the bus is a grounded bus.
